(19) United States
(12) Patent Application Publication
(10) Pub. No.: US 2025/0344543 A1
(43) Pub. Date: Nov. 6, 2025

(54) STACKED SEMICONDUCTOR DEVICE WITH METAL PAD FOR REDUCED VOLTAGE DROP

(71) Applicant: OMNIVISION TECHNOLOGIES, INC., Santa Clara, CA (US)

(72) Inventors: Qin Wang, San Jose, CA (US); Xin Wang, San Jose, CA (US)

(21) Appl. No.: 18/656,194

(22) Filed: May 6, 2024

(51) Int. Cl. H01L 27/146

(52) U.S. Cl. CPC H10F 39/811; H10F 39/809; H10F 39/182

(57) ABSTRACT

A stacked semiconductor device comprising a first die including a first semiconductor substrate and a first interconnect, a second die including a second semiconductor substrate and a second interconnect, a plurality of first bonding pads disposed within the first interconnect stack, a plurality of second bonding pads disposed within the second interconnect stack, and a metal pad embedded within the first semiconductor substrate is described. The plurality of first bonding pads contact the plurality of second bonding pads at a bonding interface to form a plurality of bonding connections. The metal pad is coupled to a first bonding connection included in the plurality of bonding connections. The metal pad extends laterally between a first pair of bonding connections included in the plurality of bonding connections when the stacked semiconductor device is viewed from a plan view.

### TECHNICAL FIELD

This disclosure relates generally to stacked semiconductor devices, and in particular but not exclusively, relates to stacked image sensors.

### BACKGROUND INFORMATION

Stacked semiconductor devices are complementary metal-oxide semiconductor (CMOS) devices manufactured by vertically stacking and interconnecting two or more integrated circuits to form a three-dimensional integrated circuit. Advantages of stacked semiconductor devices included reduced footprint and lower operating power than conventional two-dimensional integrated circuits. Additionally, the added dimensionality in the vertical dimension enables new opportunities in design of CMOS devices.

Image sensors are one type of CMOS device that have become ubiquitous and are now widely used in digital cameras, cellular phones, security cameras, as well as, medical, automobile, and other applications. The typical image sensor operates in response to image light reflected from an external scene being incident upon the image sensor. The image sensor includes an array of pixels having photosensitive elements (e.g., photodiodes) that absorb a portion of the incident image light and generate image charge upon absorption of the image light. The image charge photogenerated by the pixels may be measured as analog output image signals on column bit lines that vary as a function of the incident image light. In other words, the amount of image charge generated is proportional to the intensity of the image light, which is readout as analog image signals from the column bit lines and converted to digital values to produce digital images (i.e., image data) representative of the external scene.

As image sensors are integrated into a broader range of electronic devices it is desirable to enhance their functionality, performance metrics, and the like in as many ways as possible (e.g., resolution, power consumption, dynamic range, size, etc.) through both device architecture design as well as image acquisition processing.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified. Not all instances of an element are necessarily labeled so as not to clutter the drawings where appropriate. The drawings are not necessarily to scale; emphasis instead being placed upon illustrating the principles being described.

FIG. 1A illustrates a cross-sectional view of a stacked semiconductor device with a metal pad for reduced voltage drop, in accordance with embodiments of the disclosure.

FIG. 1B illustrates a plan view of the stacked semiconductor device with the metal pad illustrated in FIG. 1A, in accordance with embodiments of the disclosure.

FIG. 2A illustrates a cross-sectional view of a stacked semiconductor device with metal pad for reduced voltage drop, in accordance with embodiments of the disclosure.

FIG. 2B illustrates a plan view of the stacked semiconductor device with the metal pad illustrated in FIG. 2A, in accordance with embodiments of the disclosure.

FIG. 3A illustrates a plan view of the semiconductor device with a metal pad including a plurality of having a plurality of finger portions extending from a main body portion, in accordance with an embodiment of the disclosure.

FIG. 3B illustrates a plan view of a stacked semiconductor device with a metal pad including an extended portion extending from the main body portion, in accordance with an embodiment of the disclosure.

FIG. 3C illustrates a plan view of a stacked semiconductor device with a metal pad including an extended portion extending from a main body portion, in accordance with an embodiment of the disclosure.

FIG. 4 illustrates a plan view of an image sensor with a plurality of contact pads for reduced IR drop, in accordance with an embodiment of the disclosure.

FIG. 5 is a functional block diagram of an imaging system including an image sensor with a metal pad for reduced voltage drop described in exemplary embodiments of FIG. 1A-4, in accordance with embodiments of the present disclosure.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures can be exaggerated relative to other elements to help to improve understanding of various embodiments of the present invention. In addition, common but well-understood elements that are useful or necessary in a commercially feasible embodiment are often not depicted in order to facilitate a less obstructed view of these various embodiments of the present invention.

### DETAILED DESCRIPTION

Embodiments of an apparatus, system, and/or method related to a stacked semiconductor device with metal pad for reduced voltage drop are described herein. In the following description, numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

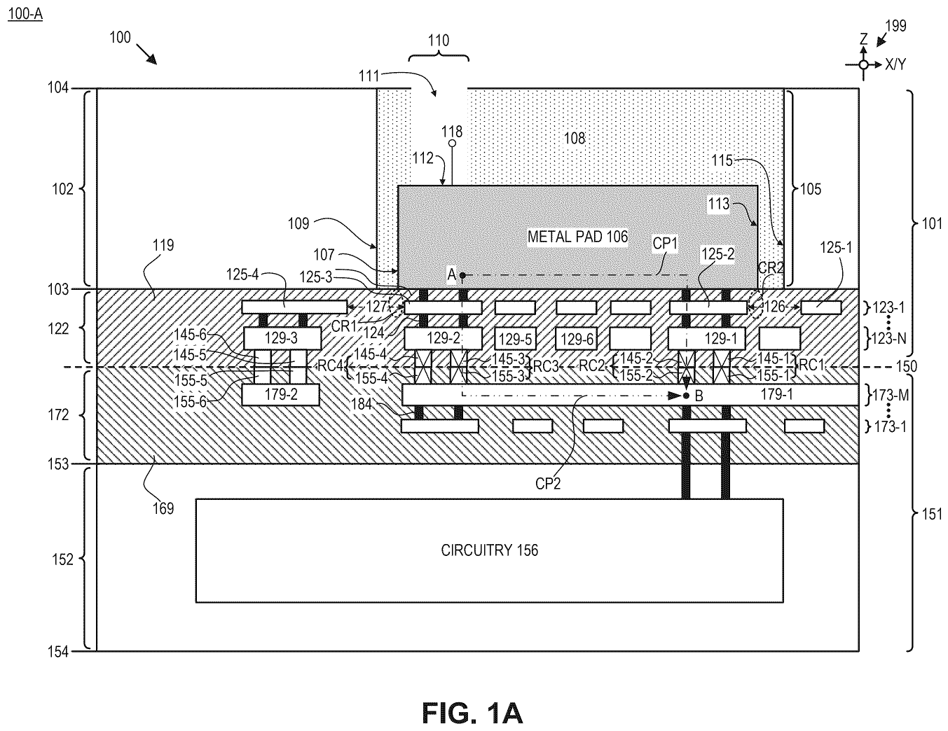

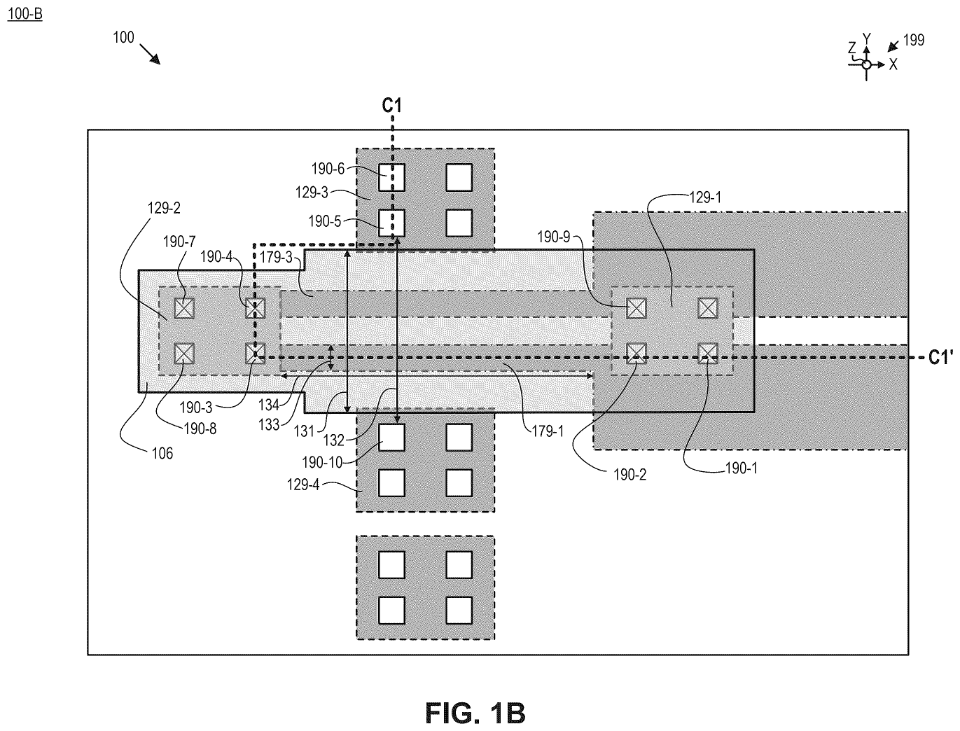

FIG. 1A illustrates a cross-sectional view 100-A of a stacked semiconductor device 100 with a metal pad 106 for reduced voltage drop, in accordance with embodiments of the disclosure. The stacked semiconductor device 100 includes a first die 101 and a second die 151. The first die 101 includes a first semiconductor substrate 102 and a first interconnect stack 122. The second die 151 includes a second semiconductor substrate 152 and a second interconnect stack 172. The stacked semiconductor device 100 further includes an isolation trench 105, the metal pad 106, isolation material 108, a first insulating medium 119, a plurality of metal layers 123, including a proximal metal layer 123-1, a distal metal layer 123-N, and zero or more additional metal layers disposed between the proximal metal layer 123-1 and the distal metal layer 123-N, a plurality of vias 124, a plurality of metal wires 125, including metal wires 125-1, 125-2, 125-3, and 125-4, a plurality of metal wires 129, including metal wires 129-1, 129-2, first bonding pads 145, including first bonding pads 145-1, 145-2, 145-3, 145-4, 145-5, and 145-6, second bonding pads 155, including second bonding pads 155-1, 155-2, 155-3, 155-4, 155-5, and 155-6, circuitry 156, a second insulating medium 169, a plurality of metal layers 173, including a proximal metal layer 173-1, a distal metal layer 173-M, and zero or more additional metal layers disposed between the proximal metal layer 173-1 and the distal metal layer 173-M, a plurality of metal wires 175 including metal wires 179-1 and 179-2, and a plurality of vias 184. Additionally, it is appreciated that the views presented in FIG. 1A-1B may omit certain elements of the stacked semiconductor device 100 to avoid obscuring details of the disclosure. In other words, not all elements of the stacked semiconductor device 100 may be labeled, illustrated, or otherwise shown within FIG. 1A-1B or other figures throughout the disclosure. For example, the stacked semiconductor device 100 may include additional semiconductor substrates and/or interconnect stacks such that the stacked semiconductor device 100 includes more than two dies and more than two interconnect stacks.

The stacked semiconductor device 100 is a complementary metal-oxide semiconductor (CMOS) device (e.g., image sensor, microprocessor, memory, application specific integrated circuit, other integrated circuit, and/or combinations thereof) formed, at least in part, by the first semiconductor substrate 102 (e.g., included in the first die 101) and the second semiconductor substrate 152 (e.g., included in the second die 151) that are vertically stacked and coupled together (e.g., electrically and physically) in a stacked chip scheme achieved via bonding (e.g., oxide bonding, metal bonding, hybrid bonding), silicon connections (e.g., through silicon vias), other suitable circuit coupling technologies, or combinations thereof at bonding interface 150.

The stacked chip scheme of the stacked semiconductor device 100 illustrated in FIG. 1A allows for distribution of components across multiple substrates (e.g., the first semiconductor substrate 102 and the second semiconductor substrate 152), which may provide various advantages to the stacked semiconductor device 100 (e.g., in terms of reduced footprint, increased performance, increased density, and the like). In some embodiments, the stacked semiconductor device 100 corresponds to a stacked image sensor in which the second semiconductor substrate 152 is utilized to offload components that would traditionally be included in the first semiconductor substrate 102. In some embodiments, the first die 101 corresponds to a pixel die when the first semiconductor substrate 102 includes photosensitive elements (e.g., a plurality of photodiodes disposed within the first semiconductor substrate 102 to form a pixel cell array) while the second die 151 corresponds to a logic die when the circuitry 156 included in or on the second semiconductor substrate 152 corresponds to pixel cell circuitry associated with the pixel cell array of the first semiconductor substrate 102 (e.g., any one of or a combination of pixel transistors such as reset transistors, source-follower transistors, row select transistors, switchable conversion gain transistors, and so on, analog to digital circuitry, signal processing circuitry, or other circuitry to facilitate imaging an external scene with the pixel cell array). It is appreciated that offloading at least part of the circuitry associated with the pixel cell array formed in or on the first semiconductor substrate 102 advantageously provides additional space on the first semiconductor substrate 102 (e.g., to reduce pixel pitch, increase photodiode sensing area relative to total pixel area, increase pixel density, and so on).

In some embodiments, the additional space may be utilized to improve performance of the stacked semiconductor device 100. For example, image sensor resolution may be improved by increasing the number of photodiodes per unit area. However, to facilitate pixel size shrinking, image sensor resolution increasing, and/or image sensor frame rate increasing there is an increased demand for additional circuitry to achieve increased readout functions. In some embodiments, additional row decoder and/or bitlines may be necessary to accommodate the increased number of photosensitive elements (e.g., photodiodes), which may suppress the critical dimension (e.g., width of metal lines or traces) for signal and power routing within the first interconnect stack 122 and the second interconnect 172 due to limited spacing. In some embodiments, routing adjacent to the bonding interface (e.g., provided by the distal metal layer 123-N within the first interconnect stack 122 and the distal metal layer 173-M within the second interconnect stack 172) may be particularly spatially limited since routing for power (e.g., to distribute input power such as analog operating voltage AVDD, digital operating voltage DVDD, and/or other supply voltage from the first die 101 to the circuitry 156 within the second die 151) and signal (row decoder, bitline, control signal, function I/O, general I/O, clock, and the like) both extend through the bonding interface 150 to interconnect the first die 101 to the second die 151. In some embodiments, analog operating voltage AVDD may be configured as a pixel reference voltage. However, when the critical dimensions for power routing are suppressed, the resistance for the metal lines used for power routing increases and may result in voltage drop or IR drop across the integrated circuit. The effect of IR drop varies depending on chip design, but could result in reduced performance, timing delays, increased power consumption, or even prevent the semiconductor device from functioning.

One way to mitigate the issue of IR drop is to increase the number of metal layers within the interconnect stacks (e.g., first interconnect stack 122 and/or second interconnect stack 172) and/or increase the physical size (e.g., lateral dimensions along the X or Y directions of the coordinate system 199) of the stacked semiconductor device 100, but both solutions result in increased manufacturing costs. Alternatively or additionally, it may be desirable to have a reduced device footprint, increased routing density, and/or otherwise facilitate increased bonding connections at the bonding interface 150 (e.g., when the stacked semiconductor device 100 is an image sensor and there is pixel-level bonding coupling individual pixels or pixel cells included in the first die 101 to components such as pixel control circuitry included in the circuitry 156 in or on the second die 151).

Embodiments of the disclosure mitigate IR drop by having the metal pad 106 (e.g., a power pad) embedded in the first semiconductor substrate 102 to provide an additional current path for input power to reduce path resistance and thus reduce IR drop. Advantageously, the metal pad 106 is not limited to the same critical dimensions at the metal wires included in the distal metal layer 123-N within the first interconnect stack 122 nor the distal metal layer 173-M within the second interconnect stack 172 and thus the metal pad 106 may have increased width and/or thickness to provide a conductive path with reduced resistance. The metal pad 106 may be formed of Au, Cu, Al, metal alloys, other metals, any other sufficiently conductive material to allow for electrical connection formation, or combinations thereof and is compatible with conventional semiconductor device processing and microfabrication techniques.

In the illustrated embodiment of FIG. 1A, the first die 101 is vertically stacked with the second die 151. The first die 101 includes the first semiconductor substrate 102 and the first interconnect stack 122 and the second die 151 includes the second semiconductor substrate 152 and the second interconnect stack 172. The first interconnect stack 122 and the second interconnect stack 172 are coupled together at the bonding interface 150 and disposed between the first semiconductor substrate 102 and the second semiconductor substrate 152. The first semiconductor substrate 102 and the second semiconductor substrate 152 may respectively correspond to a part of or an entirety of a semiconductor wafer (e.g., a silicon wafer). In some embodiments, the first semiconductor substrate 102 and/or the second semiconductor substrate 152 includes or is otherwise formed of silicon, a silicon germanium alloy, germanium, a silicon carbide alloy, an indium gallium arsenide alloy, any other alloys formed of III-V group compounds, combinations thereof, one or more epitaxial layers of the aforementioned materials, or a bulk substrate thereof. More specifically, the first semiconductor substrate 102 and/or the second semiconductor substrate 152 may correspond to any semiconductor material or combination of materials that may be doped or otherwise configured to facilitate the formation of an integrated circuit (e.g., forming individual circuitry components such as source/drain regions of transistors, memory elements, photodiodes, or the like). For example, in some embodiments, the first die 101 may correspond to a pixel die including a pixel cell array formed in the first semiconductor substrate 102. The first semiconductor substrate 102 may correspond to one or more epitaxial layers (e.g., P or N doped silicon) formed on a carrier wafer. In such an embodiment, the photodiodes included in the pixel cell array may be formed in the one or more epitaxial layers corresponding to the first semiconductor substrate 102 while the carrier wafer may be removed or otherwise thinned during fabrication to form the first die 101 which is then subsequently stacked and interconnected with the second die 151.

The metal pad 106 is embedded within the first semiconductor substrate 102 (e.g., disposed proximate to the first interconnect stack 122 between a first side 103 of the first semiconductor substrate 102 and a second side 104 of the first semiconductor substrate 102 opposite the first side 103). More specifically, the metal pad 106 is disposed within an isolation trench formed within the first semiconductor substrate 102. The isolation trench 105 is filled with an isolation material 108 (e.g., an oxide-based material such as silicon dioxide or any suitable insulation material providing electrical isolation between electrical components) surrounding the metal pad 106 to electrically isolate the metal pad 106 from a substrate material of the first semiconductor substrate 102. The isolation trench 105 includes an opening 111 extending from the second side 104 and through the isolation material 108 to expose a surface 112 of the metal pad 106. The opening 111 exposes a portion of the metal pad 106 to define a contact window 110 for the metal pad 106 to enable an external connection (e.g., supply voltage 118, which may correspond to an input power such as operating voltage AVDD powering analog circuitries or operating voltage DVDD powering digital circuitries) to the metal pad 106. In some embodiments, a dimension of the contact window 110 is defined to enable an external wiring connection (e.g., via wire bonding) for forming an external connection between the semiconductor device 100 and an external circuitry or an external device.

As illustrated, the stacked semiconductor device 100 includes the plurality of first bonding pads 145 disposed within the first interconnect stack 122 and the plurality of second bonding pads 155 disposed within the second interconnect stack 172. The plurality of first bonding pads 145 contacts the plurality of second bonding pads 155 at the bonding interface 150 to form a plurality of bonding connections, which may individually be referred to as rail connections or signal connections depending on the functionality (e.g., power routing or signal/data transfer, respectively) of the a given connection included in the plurality of bonding connections. In embodiments of the disclosure, individual rail connections included in the plurality of bonding connections are represented by an “X” extending through paired bonding pads included in the plurality of first bonding pads 145 and the plurality of second bonding pads 155 that are directly coupled together at the bonding interface 150. For example, bonding pads 145-1 and 155-1 form a first rail connection RC1, bonding pads 145-2 and 155-2 form a second rail connection RC2, bonding pads 145-3 and 155-3 form a third rail connection RC3, and bonding pads 145-4 and 155-4 form a fourth rail connection RC4. However, it is appreciated that other connections that are not explicitly marked as rail connections (e.g., a bonding connection that includes bonding pads 145-5 and 155-5 and/or another bonding connection that includes bonding pads 145-6 and 155-6) may correspond to rail connections for power routing, signal connections for data transfer, or both. In some embodiments, the plurality of first bonding pads 145 and the plurality of second bonding pads 155 are vertically aligned as illustrated. However, in other embodiments, the plurality of first bonding pads 145 and the plurality of second bonding pads 155 may not be vertically aligned. In one embodiment, bonding pads 145-2 and 155-2 that form a second rail connection RC2 may be arranged such that a center line of bonding pad 145-2 and a center line of bonding pad 155-2 is not aligned. That is, at least a vertical edge of bonding pad 145-2 and vertical edge of bonding pad 155-2 may not be aligned. In the same or another embodiment, the dimensions of bonding pads 145-2 and 155-2 may be configured to be different.

In some embodiments, the plurality of bonding connections formed by the plurality of first bonding pads 145 and the plurality of second bonding pads 155 are described as “hybrid bonds.” It is appreciated that the term “hybrid bond” refers to one or more interconnections formed via a direct bond interconnect process by which metal surfaces (e.g., Au, Cu, Al, metal alloys, other metals, and/or combinations thereof of the plurality of first bonding pads 145 and the plurality of second bonding pads 155) disposed within the insulating mediums (e.g., first insulating medium 119 included in the first interconnect stack 122 and the second insulating medium 169 included in the second interconnect stack 172) formed on two or more semiconductor substrates (e.g., the first semiconductor substrate 102 and the second semiconductor substrate 152) are placed in direct contact and permanently affixed together. In some embodiments, the metal surfaces are initially adhered together via Van der Waals bonds between the metal surfaces. One or more thermal processes may then be applied to convert the Van der Waals bonds to covalent and/or metallic bonds to permanently affix the two or more semiconductor substrates together. It is further appreciated that the one or more thermal processes may also result in bonding between one or more of the metal surfaces and the insulating medium and/or between insulating mediums on the two or more semiconductor substrates. However, in other embodiments, other suitable circuit coupling technologies (e.g. through-silicon vias, metal bonding, or the like) may be utilized to form the plurality of bonding connections.

The first interconnect stack 122 and the second interconnect 172 are hierarchical or tiered structures formed by a plurality of metal layers (e.g., the plurality of metal layers 123 included in the first interconnect stack 122 and the plurality of metal layers 173 included in the second interconnect stack 172) and a plurality of vias (e.g., the plurality of vias 124 included in the first interconnect stack 122 and the plurality of vias 184 included in the second interconnect stack 172) disposed within corresponding insulating mediums (e.g., the first insulating medium 119 included in the first interconnect stack 122 and the insulating medium 169 included in the second interconnect stack 172). The insulating mediums 119 and 169 include one or more insulating layers (e.g., one or more intra- and/or inter-metal dielectrics such as silicon dioxide, organosilicate glass such as SiCOH, porous SiCOH, other insulating materials, or combinations thereof) that separate individual metal wires (e.g., Au, Al, Cu, W, one or more alloys such as an aluminum alloy, other conductive materials, or combinations thereof) included in the plurality of metal layers 123, 173 and individual connection vias (e.g., Au, Al, Cu, W, Ru, one or more alloys such as an aluminum alloy, other conductive materials, or combinations thereof) included in the plurality of vias 124, 184. It is appreciated that individual metal wires that are positioned in adjacent tiers formed by the plurality of metal layers 123, 173 are coupled together by the plurality of vias 124, 184 to facilitate cross-substrate electrical coupling by providing power and signal routing through the first interconnect stack 122 and the second interconnect stack 172. It is appreciated that the term “metal wires” included in the plurality of metal layers 123, 173 may otherwise be described as traces, lines, pads, and the like that extend along the x/y direction and/or function as a contact pad connecting adjacent vias included in the plurality of vias 124, 184.

As discussed previously, the metal pad 106 provides a reduced resistance pathway for current to traverse (e.g., laterally along the xy-plane of the coordinate system 199) to mitigate the IR drop that may occur in other pathways with more limited (e.g., in terms of width and/or depth) critical dimensions. In the illustrated embodiment, the metal pad 106 is coupled to the first rail connection RC1 formed by bonding pads 145-1 and 155-1 the second rail connection RC2 formed by bonding pads 145-2 and 155-2, the third rail connection RC3 formed by bonding pads 145-3 and 155-3, and the fourth rail connection RC4 formed by bonding pads 145-4 and 155-4. The first, second, third, and fourth rail connections RC1, RC2, RC3, RC4 are also each coupled to metal wire 179-1 (e.g., a first metal wire included in the distal metal layer 173-M). In such a configuration, the metal pad 106 and the metal wire 179-1 are connected in parallel forming first conductive path CP1 that includes first and second rail connections RC1, RC2 and second conductive path CP2 that includes third and fourth rail connections RC3, RC4. The metal wire 179-1 is disposed within the second interconnect stack 172 and configured to deliver power (e.g., from the supply voltage 118 connected to the metal pad 106 formed in the first semiconductor substrate 102) to components formed in or on the second semiconductor substrate 152 (e.g., circuitry 156). The metal pad 106 and the metal wire 179-1 respectively provide a first conductive path and a second conductive path, each extending from disparate rail connections (e.g., laterally from the first rail connection to the fourth rail connection). In other words, the second die 151 includes circuitry 156 disposed in or on the second semiconductor substrate 152 and the metal pad 106 is coupled to the circuitry 156 through the first rail connection to provide a supply voltage 118 to the circuitry 156.

In some embodiments, the components included in the circuitry 156 includes any one of or a combination of pixel transistors such as reset transistors, source-follower transistors, row select transistors, switchable conversion gain transistors, and so on, readout circuitry, analog to digital circuitry, row driver circuitry, control circuitry, signal processing circuitry, application specific integrated circuitry, microprocessor, or other circuitry associated with the operations of the stacked semiconductor device 100 (e.g., to facilitate imaging an external scene with the pixel cell array and corresponding processing when the stacked semiconductor device 100 is configured as an image sensor).

As illustrated in FIG. 1A, the first interconnect stack 122 includes the proximal metal layer 123-1 and the distal metal layer 123-N. The proximal metal layer 123-1 is closer to the first side 103 of the first semiconductor substrate 102 than any other metal layer included in the plurality of metal layers 123 while the distal metal layer 123-N is disposed closer to the bonding interface 150 than any other metal layer included in the plurality of metal layers 123. Similarly, the second interconnect stack 172 includes the distal metal layer 173-M, which is closer to the bonding interface 150 than any other metal layer included in the plurality of metal layers 173. It is appreciated that the plurality of metal layers 123, 173 each provide lateral routing (e.g., x- or y-direction of the coordinate system 199) while the plurality of vias 124, 184 provide vertical routing (e.g., z-direction of the coordinate system 199). The distal metal layer 173-M is formed of metal wires 179 (e.g., 179-1 and 179-2). As previously discussed, the metal pad 106 and the metal wire 179-1 respectively provide the first conductive path and the second conductive path that are coupled in parallel for distributing power (e.g., operating voltage AVDD or DVDD) across the stacked semiconductor device 100.

It is appreciated that the first conductive path CP1 and the second conductive path CP2 are current flow pathways (e.g., from A to B illustrated in FIG. 1A) arranged to provide parallel connections between the supply voltage 118 and the circuitry 156 via the metal pad 106 and the metal wire 179-1, respectively, to reduce IR drop. In other words, the first conductive path CP1 may extend laterally (e.g., along the xy-plane of coordinate system 199) primarily through metal pad 106 and vertically through metal wire 129-1 and corresponding bonding pads. The second conductive path CP2 may extend vertically (e.g., along the z-direction of coordinate system 199) through metal wires 129-2 and corresponding bonding pads and laterally (e.g., along the xy-plane of coordinate system 199 primarily through metal wire 179-1). As such two-equivalent or parallel pathways from point A to point B may be achieved and IR drop between points A and B is reduced. It is appreciated that points A and B are merely illustrated as one possible example to show that IR drop is achieved by having parallel circuit connections (e.g., between supply voltage 118 and circuitry 156), in accordance with embodiments of the disclosure.

The first and second conductive paths CP1, CP2 also extend through metal wires included in the proximal metal layer 123-1 (e.g., metal wires 125-2 and 125-3) and the distal metal layer 123-N(e.g., metal wires 129-1 and 129-2) to traverse the z-direction of the coordinate system 199 (a direction normal to a surface of the first side 103 of the first semiconductor substrate 102). However, it is appreciated since the metal pad 106 and the isolation trench 105 extend to the first side 103 of the first semiconductor substrate 102 from the second side 104 of the first semiconductor substrate 102, that some embodiments may have limitations in the placement of the metal wires included in the proximal metal layer 123-1 (e.g., to increase space utilization with the first interconnect stack 122). Specifically, in some embodiments, metal wires included in the proximal metal layer 123-1 do not overlap or otherwise align with respective boundaries 107, 113, 109, 115 (e.g., outer boundaries defining a perimeter) of the metal pad 106 and/or isolation trench 105 such as in regions CR1 and CR2 as etching damage to the metal wires included in the proximal metal layer 123-1 within regions CR1 and CR2 may occur during formation of the metal pad 106 proximate to the respective boundaries 107, 113, 109, 115. Accordingly, in some embodiments, the proximal metal layer 123-1 includes adjacent proximal wires (e.g., a first pair corresponding to metal wires 125-1 and 125-2 and/or a second pair corresponding to metal wires 125-3 and 125-4) that do not have any intervening metal wires included in the proximal metal layer 123-1 disposed therebetween. For example, metal wire 125-1 is separated from metal wire 125-2 by a separation region 126 within the first interconnect stack 122 with no intervening metal wires included in the proximal metal layer 123-1 disposed within the separation region 126 and respective boundaries 113, 115 of the metal pad 106 and the isolation trench 105 overlap with the separation region 126. In another example, metal wire 125-3 is separated from metal wire 125-4 by a separation region 127 within the first interconnect stack 122 with no intervening metal wires included in the proximal metal layer 123-1 disposed within the separation region 127 and respective boundaries 107, 109 of the metal pad 106 and the isolation trench 105 overlap with the separation region 127. In other words, the respective boundaries 107, 113, 109, 115 of the metal pad 106 and/or the isolation trench 105 do not overlap with any metal wires included in the proximal metal layer 123-1.

FIG. 1B illustrates a plan view 100-B of the stacked semiconductor device 100 with the metal pad 106 illustrated in FIG. 1A, in accordance with embodiments of the disclosure. It is appreciated that the cross-sectional view 100-A of the stacked semiconductor device 100 illustrated in FIG. 1A is along the cutline C1-C1′ extending along the x- or y-direction of the coordinate system 199 while the plan view 100-B illustrated in FIG. 1B provides a view of the xy-plane and thus shows vertically overlapping features (e.g., with respect to the z-direction of the coordinate system 199) of the stacked semiconductor device 100. For example, the metal wires 129-1 and 129-2 are disposed between the metal pad 106 and a plurality of bonding connections 190 with respect to the z-direction of the coordinate system 199.

The plurality of bonding connections 190 (e.g., 190-1, 190-2, 190-3, 190-4, 19-4, 190-5, 190-6, 190-7, 190-8, 190-9, 190-10) are shown with each individual bonding connection corresponding to paired bonding pads including in the plurality of first bonding pads 145 and the plurality of second bonding pads 155 illustrated in FIG. 1A that are directly coupled together at the bonding interface 150. For example, bonding connection 190-1 illustrated in FIG. 1B corresponds to paired bonding pads 145-1 and 155-1 illustrated in FIG. 1A, bonding connection 190-2 illustrated in FIG. 1B corresponds to paired bonding pads 145-2 and 155-2 illustrated in FIG. 1A, bonding connection 190-3 illustrated in FIG. 1B corresponds to paired bonding pads 145-3 and 155-3 illustrated in FIG. 1A, bonding connection 190-4 illustrated in FIG. 1B corresponds to paired bonding pads 145-4 and 155-4 illustrated in FIG. 1A, bonding connection 190-5 illustrated in FIG. 1B corresponds to paired bonding pads 145-5 and 155-5 illustrated in FIG. 1A, bonding connection 190-6 illustrated in FIG. 1B corresponds to paired bonding pads 145-6 and 155-6 illustrated in FIG. 1A, and so on. As previously discussed, some of the plurality of bonding connections 190 correspond to rail connections, which are represented by an “X” and facilitate power distribution across the stacked semiconductor device 100. As illustrated, the rail connections vertically overlap with the metal pad 106 and the metal wires 179-1 and 179-3 to provide multiple conductive paths. In some embodiments, the metal pad 106 and the metal wires 179-1 and 179-3 are arranged such that the metal pad 106 covers, at least in part, the metal wires 179-1 and 179-3 when viewed from the plan view 100-B. In other words, the metal pad 106 extends over the metal wires 179-1 and 179-3.

The plan view 100-B illustrated in FIG. 1B shows at least three conductive paths for distributing power across the multiple dies of the stacked semiconductor device 100. The three conductive paths include a first conductive path provided by the metal pad 106, a second conductive path provided by the metal wire 179-1, and a third conductive path provided by the metal wire 179-3. Specifically, the metal pad 106 is configured to receive input power (e.g., via supply voltage 118 illustrated in FIG. 1A). The metal pad 106 is coupled to one or more metal wires located within the distal metal layer 173-M (e.g., metal wires 179-1 and 179-3) included in the second interconnect stack at one or more locations (e.g., via bonding connections 190-1, 190-2, 190-3, 190-4, or other bonding connections represented by an “X” or otherwise referred to as rail connections) to increase the number of conductive paths for power routing while reducing IR drop and maintaining or improving interconnect density. As illustrated, the metal wire 179-1 is coupled to bonding connections 190-2 and 190-3 to provide the second conductive path extending from the bonding connections 190-2 2 190-3 while the metal wire 179-3 is coupled to bonding connections 190-4 and 190-9 to provide the third conductive path extending from the bonding connections 190-4 to 190-9.

The metal wires 179-1 and 179-3 are included in the distal metal layer 173-M of the second interconnect stack 172 (see, e.g., FIG. 1A) and are disposed between one or more pairs of bonding connections included in the plurality of bonding connections 190 (e.g., bonding connections 190-5 and 190-10). The metal wires 179-1 and 179-3 may be spatially constricted due to the plurality of bonding connections 190 (e.g., as the density of the plurality of bonding connections 190 increased, the metal wires 179-1 and 179-3 may be constrained in width) with may result in increased IR drop due to increased resistance. In contrast, the metal pad 106 does not have the same lateral limitations. The metal pad 106 extends laterally between a first pair (e.g., 190-5 and 190-10) of the plurality of bonding connections 190 when the stacked semiconductor device 100 is viewed from the plan view 100-B. In some embodiments, the first pair of the plurality of bonding connections correspond to signal connections (e.g., for signal or data transfer). The metal pad 106 extends between a first pair of rail connections (e.g., 190-2 and 190-3) when the stacked semiconductor device 100 is viewed from the plan view 100-B. The metal pad 106 extends between a second pair of rail connections (e.g., 190-4 and 190-9) when the stacked semiconductor device 100 is viewed from the plan view 100-B.

In some embodiments, the metal pad 106 defines a lateral area greater than a combined lateral area of underlying metal wires (e.g., metal wires 179-1 and 179-3) disposed within the distal metal layer (e.g., 123-N and/or 173-M illustrated in FIG. 1A). The metal wire 179-1 extends (e.g., along length 134) between the first pair of rail connections included in the plurality of bonding connections 190 (e.g., bonding connections 190-2 and 190-3) while the metal wire 179-3 extends between a second pair of rail connections (e.g., bonding connections 190-4 and 190-9) included in the plurality of bonding connections 190. In some embodiments, the metal wire 179-3 extends alongside (e.g., parallel) and adjacent to the metal wire 179-1 and has substantially the same dimensions. It is appreciated that the metal wires 179-1 and 179-3 are both disposed between the first pair of bonding connections (e.g., 190-5 and 190-10) and furthermore are at least partially covered by the metal pad 106 when the stacked semiconductor device 100 is viewed from the plan view 100-B. As illustrated, a first width 131 of metal pad 106 is greater than a second width 133 of the metal wire 179-1 which mitigates IR drop that may otherwise affect the stacked semiconductor device 100 without the presence of the metal pad 106. It is appreciated that a corresponding width of the metal wire 179-3 may be the same or different as the second width 133 of the metal wire 179-1. In some embodiments, the first conductive path (e.g., defined by the metal pad 106), the second conductive path (e.g., defined by the metal wire 179-1), and the third conductive path (e.g., defined by the metal wire 179-3) extend from respective rail connections (e.g., 190-2, 190-3, 190-4, 190-9, and so on) a distance along a first direction (e.g., defined by length 134). Individual bonding connections included in the first pair of the plurality of bonding connections 190 (e.g., 190-5 and 190-10) are separated by a second distance (e.g., separation distance 132) extending a long a second direction perpendicular to the first direction when viewed from the plan view. For example, the length 134 extends along the x-direction of the coordinate system 199 while the separation distance 132 extends along the y-direction of the coordinate system 199.

In some embodiments, the plurality of bonding connections 190 include metal-metal bonds associated with the plurality of first bonding pads 145 contacting the plurality of second bonding pads 155 (e.g., as illustrated in FIG. 1A). In the same or other embodiments, individual bonding pads included in the plurality of first bonding pads 145 and the plurality of second bonding pads 155 are arranged in rows and columns to form an array of bonding connections collectively corresponding to or otherwise included in the plurality of bonding connections 190. For example, the first pair of bonding connections (e.g., 190-5 and 190-10) are in a same column included in the columns but different rows included in the rows. and wherein the metal pad extends between the different rows when viewed from the plan view.

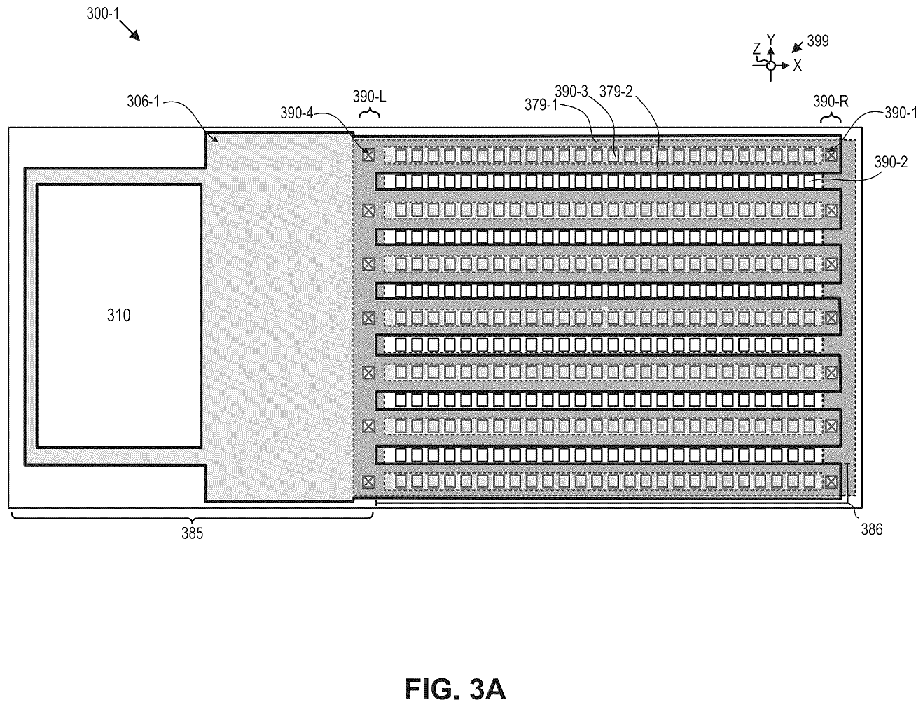

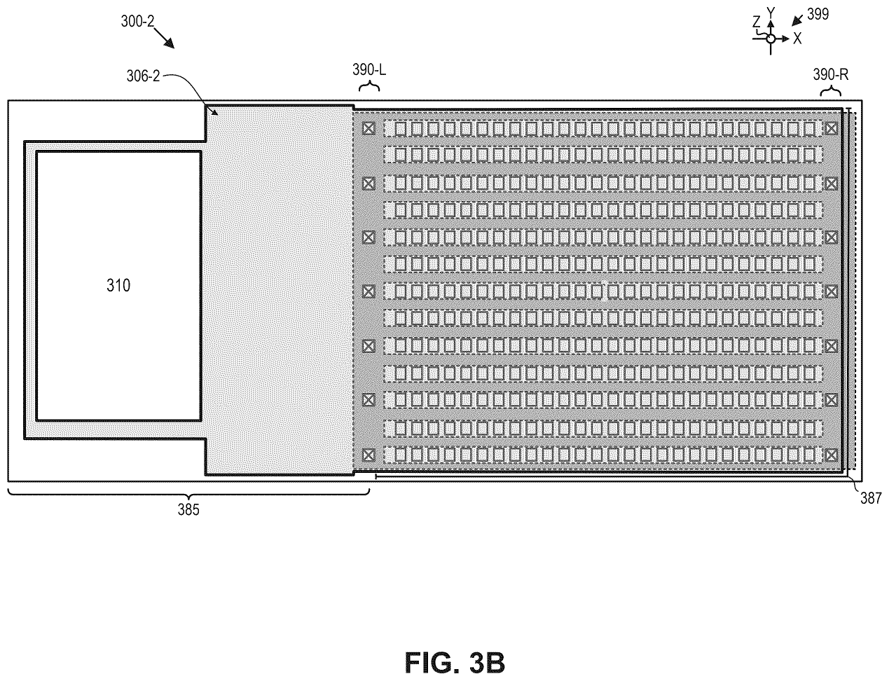

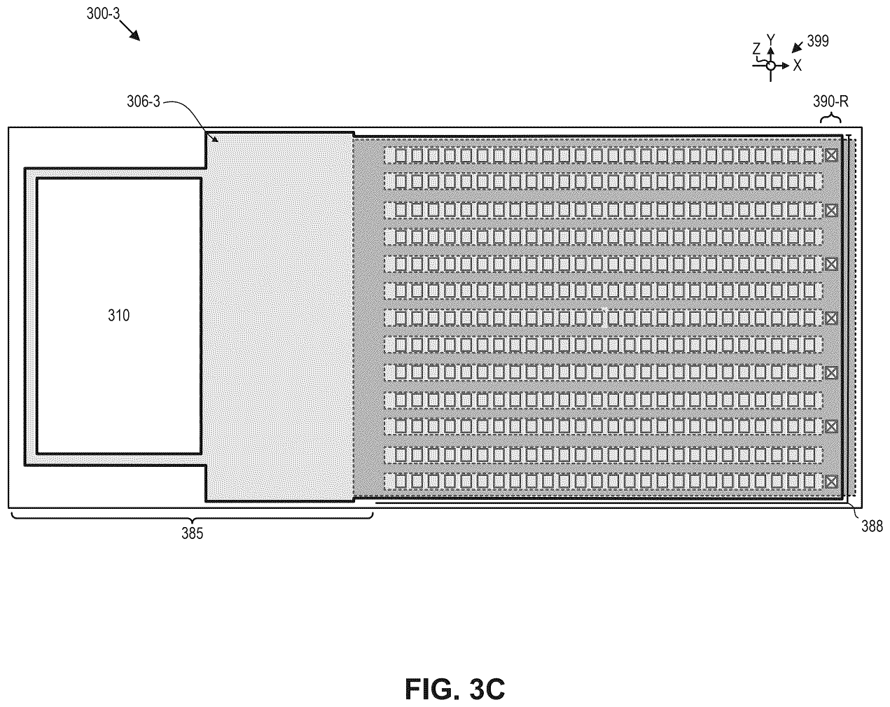

As discussed previously, the “metal wires” included in the plurality of metal layers 123, 173 may otherwise be described as traces, lines, pads, and the like that extend along the x/y direction and/or function as a contact pad connecting adjacent vias included in the plurality of vias 124, 184. For example, the metal wires 179-1 and 179-3 extend longitudinally to provide respective conductive paths along a lateral distance (e.g., the length 134) while metal wires 129-1, 129-2, 129-3, 129-4, 129-5, and 120-6 represent contact pads or metal interconnects coupled to respective groups of bonding connections included in the plurality of bonding connections 190. In the illustrated embodiment, the metal wires 129-1, 129-2, 129-3, and 129-4 are each directly coupled to respective groups of four connection pads included in the plurality of connection pads included in the plurality of bonding connections 190, which may improve the coupling between the respective dies of the stacked semiconductor device 100. For example, metal wire 129-2 is directly coupled to bonding connections 190-3, 190-4, 190-7, and 190-8. In the illustrated embodiment, there are multiple metal wires (e.g., metal wire 179-1 and 179-3) disposed between adjacent bonding connections (e.g., 190-5 and 190-10). However, in other embodiments (see, e.g., FIG. 3A-3C), there may be only one metal wire disposed between adjacent bonding connections included in the plurality of bond connections 190 when the stacked semiconductor device 100 is viewed from the plan view 100-B.

It is appreciated that metal wires 129-3 and 129-4 and respective groups of bonding connections included in the plurality of bonding connections 190 coupled thereto are electrically isolated from the metal pad 106. In the illustrated embodiment, metal wires 129-5 and 129-6 are arranged vertically between metal pad 106 and the second semiconductor substrate 152 of the second die 151. In some embodiments, metal wires 129-5 and 129-6 are configured to provide other signal connections (e.g., not power routing such as data signal routing) and thus may be further configured to be electrically isolated from the metal pad 106.

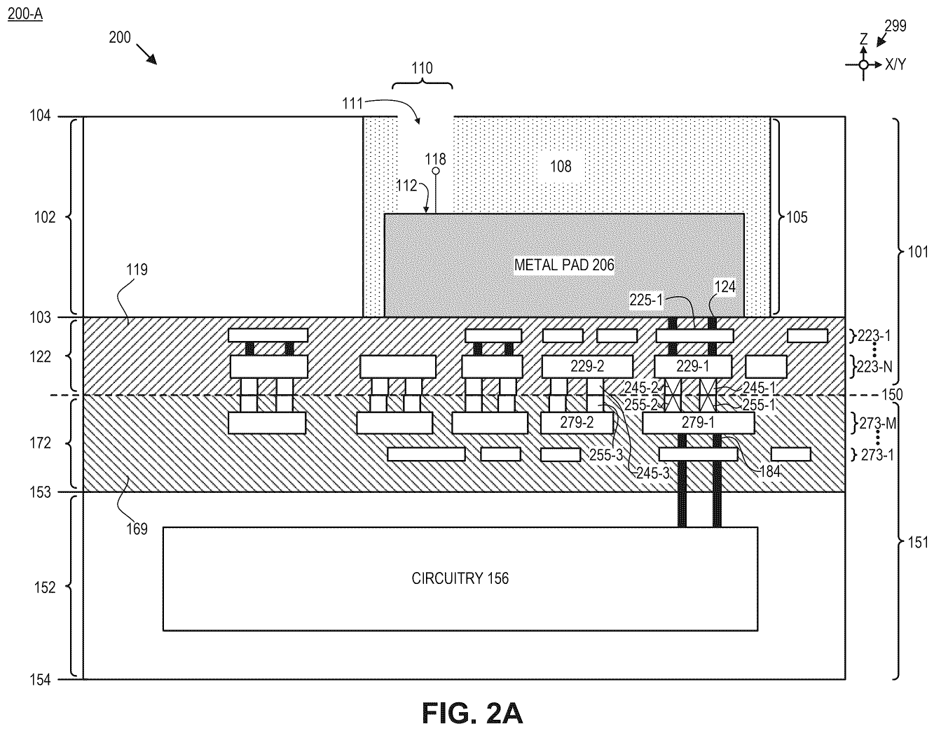

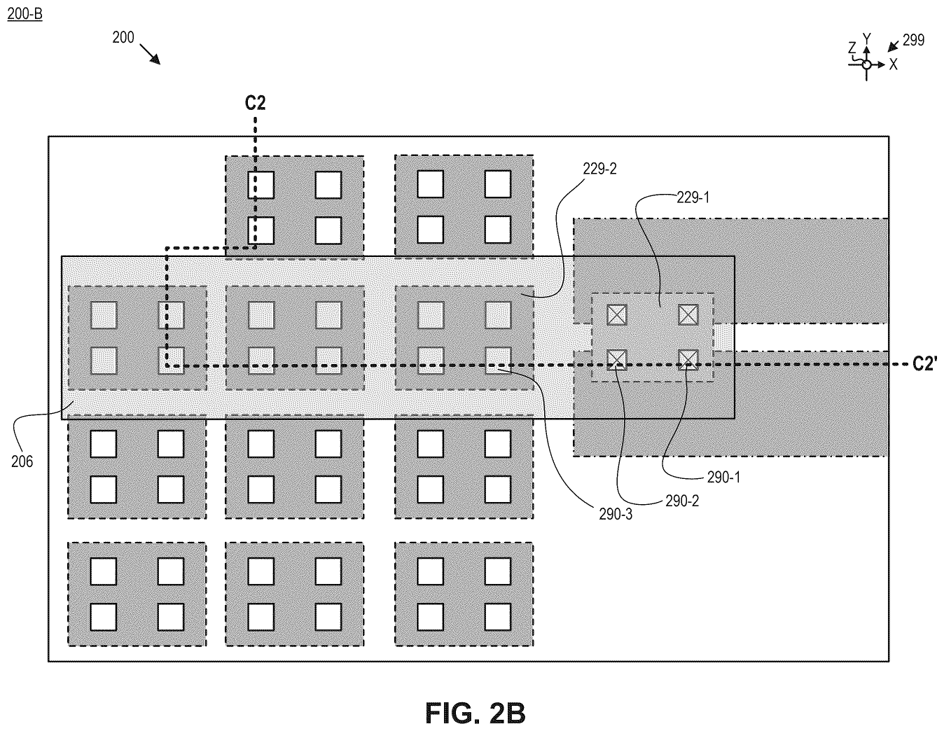

FIGS. 2A and 2B respectively illustrate a cross-sectional view 200-A and a plan view 200-B of a stacked semiconductor device 200 with metal pad 206 for reduced voltage drop, in accordance with embodiments of the disclosure. It is appreciated that the cross-sectional view 200-A of the stacked semiconductor device 200 illustrated in FIG. 2A is along the cutline C2-C2′ extending along the x- or y-direction of the coordinate system 299 while the plan view 200-B illustrated in FIG. 2B provides a view of the xy-plane and thus shows vertically overlapping features (e.g., with respect to the z-direction of the coordinate system 299) of the stacked semiconductor device 200. The stacked semiconductor device 200 of FIG. 2A-2B is similar in many regards to the stacked semiconductor device 100 of FIG. 1A-1B and includes many of the same or similar features. Accordingly, there are many elements, like-labeled or otherwise, included in the stacked semiconductor device 200 that have a corresponding counterpart included in the stacked semiconductor device 100. In other words, the stacked semiconductor device 200 is one possible variation of the stacked semiconductor device 100 illustrated in FIG. 1A-1B with metal pad for reduced IR drop. However, it is appreciated that not all elements of the stacked semiconductor device 200 may be labeled, illustrated, or otherwise shown within FIG. 2A-2B or other figures throughout the disclosure.

In the illustrated embodiment of FIG. 2A-2B, the stacked semiconductor device 200 differs from the stacked semiconductor device 100 of FIG. 1A-1B due, at least in part, to a different arrangement, position, size, or other configuration of a plurality of metal layers 223, 273 (e.g., relative to the plurality of metal layers 123, 173), a plurality of first bonding pads 245 (e.g., relative to the plurality of first bonding pads 145), a plurality of second bonding pads 255 (e.g., relative to the plurality of second bonding pads 155), and the metal pad 206. Specifically, the metal pad 206 embedded in the first semiconductor substrate 102 is of sufficient size (e.g., in terms of lateral dimensions along the xy-plane of the coordinate system 299) to have resistance low enough that the long metal wire interconnects disposed in the second interconnect stack 172 may be omitted. In such an embodiment, the second and third conductive paths (e.g., metal wire 179-1 and 179-3 illustrated in FIG. 1A-1B are omitted and the first conductive path provided by the metal pad 206 provides the supply voltage 118 to the circuitry 156 included in or on the second semiconductor substrate 152. Consequently, first bonding pads 245-1, 245-2 and second bonding pads 255-1, 255-2 correspond to rail connections that couple the metal pad 206 to the circuitry 156 while the first bonding pad 245-3 and the second bonding pad 255-3 may correspond to rail connections or signal connections. In other words, additional bonding connections extending through the bonding interface 150 may be formed under the metal pad 206 when viewed from the plan view 200-B illustrated in FIG. 2B. Such a configuration may also allow for the signal and power routing provided by the plurality of metal layers 223, 273 to take advantage of the extra space under the metal pad 206, which enables routing flexibility. For example, metal wire 225-1 included in proximal metal layer 223-1, metal wire 229-1 included in distal metal layer 223-N, metal wire 279-1 included in distal metal layer 273-M, and a metal wire included in proximal metal layer 273-1 may each vertically overlap one another to couple the metal pad 206 to the circuitry 156 in a manner similar to that of the stacked semiconductor device 100 illustrated in FIG. 1A. However, the metal wire 229-2 and 279-2 (e.g., bonding connection 290-3 illustrated in FIG. 2B), which is disposed under the metal pad 206, may be utilized for power or signal routing when previously space may have been constrained (e.g., by the metal wire 179-1 illustrated in FIG. 1A-1B). The plan view 200-B illustrated in FIG. 2B shows the plurality of bonding connections 290-1 and 290-2 correspond to rail connections that couple the metal pad 206 to the circuitry 156 while bonding connection 290-3 disposed under the metal pad 206 may provide power or signal routing.

FIG. 3A-3C show expanded plan views of stacked semiconductor devices 300-1, 300-2, and 300-3 that include different configurations of a metal pad 306 for reduced IR drop, in accordance with embodiments of the disclosure. It is appreciated that expanded plan views of FIG. 3A-3C provide a view of the xy-plane of the coordinate system 399 and thus shows vertically overlapping features (e.g., with respect to the z-direction of the coordinate system 399) of the stacked semiconductor device 300-1, 300-2, and 300-3. The stacked semiconductor devices 300-1, 300-2, and 300-3 of FIG. 3A-3B are similar in many regards to the stacked semiconductor device 100 of FIG. 1A-1B and/or the stacked semiconductor device 200 of FIG. 2A-2B and may include many of the same or similar features. Accordingly, there are many elements, like-labeled or otherwise, included in the stacked semiconductor devices 300-1, 300-2, and 300-3 that have a corresponding counterpart included in the stacked semiconductor device 100 and/or the stacked semiconductor device 200. In other words, the stacked semiconductor devices 300-1, 300-2, and 300-3 are possible variations of the stacked semiconductor device 100 illustrated in FIG. 1A-1B and/or the stacked semiconductor device 200 illustrated in FIG. 2A-2B. However, it is appreciated that not all elements of the stacked semiconductor devices 300-1, 300-2, and/or 300-3 may be labeled, illustrated, or otherwise shown within FIG. 3A-3C or other figures throughout the disclosure.

FIG. 3A illustrates a plan view of the stacked semiconductor device 300-1 with a metal pad 306-1 including a plurality of having a plurality of finger portions 386 extending from a main body portion 385, in accordance with an embodiment of the disclosure. The main body portion 385 defines a contact window 310 to receive input power (e.g., a supply voltage, which may correspond to voltage AVDD or DVDD), for example via wire bonding operation. The plurality of finger portions 386 each define respective conductive pathways embedded in a semiconductor substrate (e.g., the first semiconductor substrate 102 of FIG. 1A-2B) for reduced IR drop. As illustrated, the metal pad 306 is coupled to rail connections (e.g., bonding connections 390-R and 390-L, which includes 390-1 and 390-4) included in a plurality of bonding connections 390. It is appreciated that rail connections included in the plurality of bonding connections 390 are denoted by an “X” in FIG. 3A-3C and other figures throughout the disclosure while other connections (e.g., 390-2 and 390-3) that may be rail connections or signal connections included in the plurality of bonding connections 390 do not have an “X” annotation. Each of the plurality of finger portions 386 define a conductive pathway extending a length along the x-direction of coordinate system 399 from bonding connections 390-L to bonding connections 390-R. The bonding connections 390-L and 390-R are respectively separated from one another and positioned proximate to opposite ends of the plurality of finger portions 386. Each of the plurality of finger portions 386 are also aligned to vertically cover at least two metal wires (e.g., 379-1 and 379-2) that define respective conductive pathways disposed within a metal interconnect stack of a second die (e.g., the second interconnect stack 172 included in the second die 151 illustrated in FIG. 1A-2B). Each of the plurality of finger portions 386 are also aligned to vertically cover at least one row of the plurality of bonding connections 390. In some embodiments, rows of the plurality of bonding connections 390 are alternately covered and uncovered by a corresponding one of the plurality of finger portions 386.

FIG. 3B illustrates a plan view of the stacked semiconductor device 300-2 with a metal pad 306-2 including an extended portion 387 extending from the main body portion 385, in accordance with an embodiment of the disclosure. The metal pad 306-2 illustrated in FIG. 3B is similar in many regards to the metal pad 306-1 illustrated in FIG. 3A. One difference is that the extended portion 387 does not form separated fingers that each define respective conductive pathways. Accordingly, the extended portion 387 of the metal pad 306-2 covers two or more adjacent rows of the plurality of bonding connections to define a wider conductive pathway, which may have reduced resistance relative to the metal pad 306-1.

FIG. 3C illustrates a plan view of the stacked semiconductor device 300-3 with a metal pad 306-3 including an extended portion 388 extending from a main body portion 385, in accordance with an embodiment of the disclosure. The metal pad 306-3 illustrated in FIG. 3B is similar in many regards to the metal pad 306-2 illustrated in FIG. 3B. One difference is the metal pad 306-3 provides sufficient width (e.g., reduced resistance) that the plurality of bonding connections 390-L may be omitted. In the illustrated embodiment, a singular column of bonding connections (e.g., bonding connections 390-R) electrically couples the metal pad 306-3 to the underlying die (e.g., the second die 151).

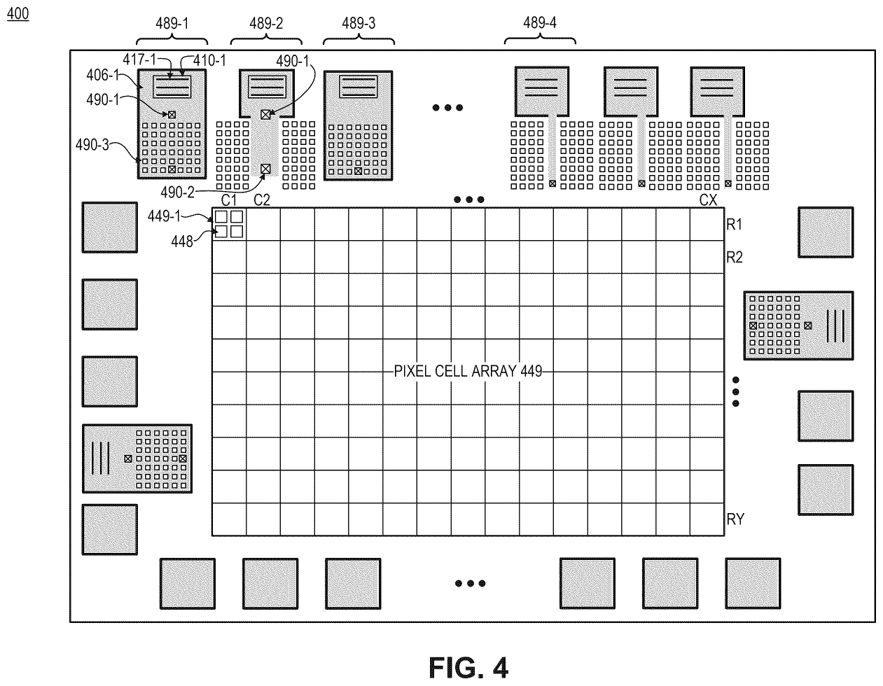

FIG. 4 illustrates a plan view of an image sensor 400 with a plurality of contact pads 489 for reduced IR drop, in accordance with an embodiment of the disclosure. The image sensor 400 is one possible implementation of the stacked semiconductor devices 100, 200, 300-A, 300-B, and/or 300-C illustrated in FIG. 1A-3C and may include the same or similar features. However, it is appreciated that not all elements of the image sensor 400 may be labeled, illustrated, or otherwise shown within FIG. 4 or other figures throughout the disclosure. The image sensor 400 includes at least two interconnected dies (e.g., the first die 101 and the second die 151). The first die, as illustrated in FIG. 4, corresponds to a pixel die and includes a plurality of photodiodes 448 disposed within a first semiconductor substrate (e.g., first semiconductor substrate 102) arranged in rows and columns (e.g., R1, R2, RY and C1, C2, and CX) to form pixel cell array 449. Each pixel cell included in the pixel cell array 449 may include one or more photodiodes included in the plurality of photodiodes 448. In the illustrated embodiment, the pixel cell 449-1 includes a two-by-two arrangement of four photodiodes included in the plurality of photodiodes. However, in other embodiments, each pixel cell may include any number of photodiodes such as 1, 2, 4, 8, or more photodiodes per pixel cell.

The first die further includes the plurality of contact pads 489 (e.g., 489-1, 489-2, 489-3, and 489-4) surrounding the pixel cell array 449 when viewed from the plan view. The plurality of contact pads 489 each include a respective metal pad 406 (e.g., 406-1 of contact pad 489-1) with an opening defining a contact window 410 (e.g., contact window 410-1 of contact pad 489-1) for physically coupling the plurality of contact pads 489 to an external connection. The plurality of contact pads 489 may correspond to power/ground pads (e.g., to receive an input or reference voltage) and non-power pads such as contact pad 489-4 (e.g., function I/O pads, general I/O, clock, data I/O, and the like). Each of the plurality of contact pads 489 may optionally include one or more contact trenches 417 (e.g., 417-1) in the respective contact window 410 (e.g., contact window 410-1) extending into a proximal metal layer of the underlying interconnect stack (e.g., proximal metal layer 123-1 of FIG. 1A). It is appreciated that both the plurality of photodiodes 448 and the metal pads 406 (e.g., 406-1 included in contact pad 489-1) laterally surrounding the plurality of photodiodes 448 are disposed or otherwise embedded within the first semiconductor substrate (e.g., between the first side 103 and the second side 104). The metal pad 406 included in each of the plurality of contact pads 489 that correspond to a power pad structure are coupled to one or more of a plurality of bonding connections 490 (e.g., rail connections), which are denoted by an “X.” For example, contact pads 489-1, 489-2, and 489-3 each correspond to power pad structures (e.g., to deliver input power to various components of the first and/or second die included in the image sensor 400) and bonding connections 490-1 and 490-2 correspond to rail connections while bonding connection 490-3 may be a rail connection or a signal connection. In some embodiments, the metal pad 406 included for power or ground pads may have a larger dimension than a metal pad included for non-power pads.

It is appreciated that the metal pad 406 included in each of the plurality of contact pads 489 for rail connection (e.g., power or ground routing) may have different configurations, in accordance with embodiments of the disclosure. In one embodiment, the metal pad 406 covers or overlaps the plurality of bonding connections 490 (e.g., as shown by contact pad 489-3 with a singular coupled bonding connections “X” and contact pad 489-1 with two coupled bonding connections “X” electrically isolated with all other non “X” denoted bonding connection). In another embodiment, the metal pad 406 is disposed between (when viewed from a top view) the plurality of bonding connections 490 (e.g. as shown in contact pad 489-2 between two group of bonding pads included in an array of bonding connections) but for coupled bonding connections denoted by the “X” (e.g., the metal pad 406 is electrically isolated from all bonding connection except to bonding connections denoted by the “X” 490-1, 490-2).

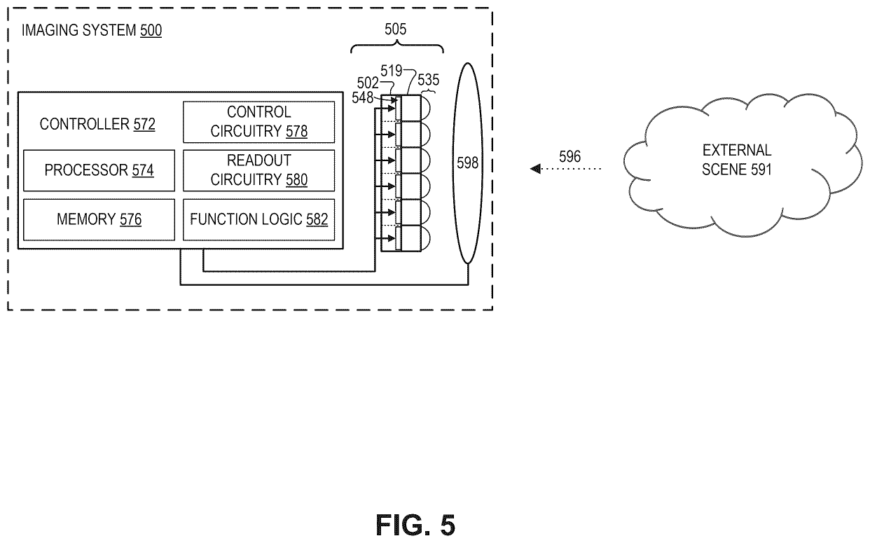

FIG. 5 is a functional block diagram of an imaging system 500 (e.g., an image sensor) including a first die 505 with a metal pad for reduced voltage drop (e.g., metal pad 106, 206, 306-1, 306-2, 306-3, and/or 406) described in exemplary embodiments of FIG. 1A-4, in accordance with embodiments of the present disclosure. The imaging system 500 is one possible implementation of the stacked semiconductor devices 100, 200, 300-A, 300-B, 300-C, and/or 400 illustrated in FIG. 1A-4 and may include the same or similar features. However, it is appreciated that not all elements of the imaging system 500 may be labeled, illustrated, or otherwise shown within FIG. 5 or other figures throughout the disclosure. The imaging system 500 includes at least two interconnected dies (e.g., the first die 505 corresponding to the first die 101 and a second die that corresponds to the second die 151). The first die 505 includes one or more a metal pads embedded within a first semiconductor substrate (e.g., first semiconductor substrate 102 illustrated in FIG. 1A-1B) for reduced voltage drop in accordance with embodiments of the disclosure. The imaging system 500 includes the first die 505 to generate electrical or image signals in response to incident light 596 and objective lens(es) 598 with adjustable optical power to focus on one or more points of interest within the external scene 591. The imaging system 500 further includes controller 572 to control, inter alia, operation of the image sensor 505 and the objective lens(es) 598. It is appreciated that the components of the controller 572 may be distributed between the at least two interconnected dies of the imaging system 500 or solely contained within a die separate from the first die 505. The first die 505 is a simplified schematic showing a first semiconductor substrate 502 with a plurality of photodiodes 548 disposed within respective portions of the semiconductor substrate 502, a plurality of color filters 519, and a plurality of microlenses 535. The controller 572 includes one or more processors 574, memory 576, control circuitry 578, readout circuitry 580, and function logic 582.

The controller 572 includes logic and/or circuitry to control the operation (e.g., during pre-, post-, and in situ phases of image and/or video acquisition) of the various components of imaging system 500. The controller 572 can be implemented as hardware logic (e.g., application specific integrated circuits, field programmable gate arrays, system-on-chip, etc.), software/firmware logic executed on a general-purpose microcontroller or microprocessor, or a combination of both hardware and software/firmware logic. In one embodiment, the controller 572 includes the processor 574 coupled to memory 576 that stores instructions for execution by the controller 572, the processor 574, and/or one or more other components of the imaging system 500. The instructions, when executed, can cause the imaging system 500 to perform operations associated with the various functional modules, logic blocks, or circuitry of the imaging system 500 including any one of, or a combination of, the control circuitry 578, the readout circuitry 580, the function logic 582, image sensor 505, objective lens 598, and any other element of imaging system 500 (illustrated or otherwise). The memory is a non-transitory computer-readable medium that can include, without limitation, a volatile (e.g., RAM) or non-volatile (e.g., ROM) storage system readable by controller 572. It is further appreciated that the controller 572 can be a monolithic integrated circuit, one or more discrete interconnected electrical components, or a combination thereof, which may be formed on one or more substrates that are coupled together. Additionally, in some embodiments one or more electrical components can be coupled together to collectively function as controller 572 for orchestrating operation of the imaging system 500.

Control circuitry 578 can control operational characteristics of the array formed by the plurality of photodiodes 548 (e.g., exposure duration, when to capture digital images or videos, and the like). Readout circuitry 580 reads or otherwise samples the analog signal from the individual photodiodes (e.g., read out electrical signals generated by each of the plurality of photodiodes 548 in response to incident light to generate image signals for capturing an image frame, and the like) and can include amplification circuitry, analog-to-digital (ADC) circuitry, image buffers, or otherwise. In the illustrated embodiment, readout circuitry 580 is included in controller 572, but in other embodiments readout circuitry 580 can be separate from the controller 572. Function logic 582 is coupled to the readout circuitry 580 to receive image data to de-mosaic the image data and generate one or more image frames. In some embodiments, the electrical signals and/or image data can be manipulated or otherwise processed by the function logic 582 (e.g., apply post image effects such as crop, rotate, remove red eye, adjust brightness, adjust contrast, or otherwise). In some embodiments, all or part of the controller 572 may be disposed within a die separated from the first semiconductor substrate 502 (e.g., a second die such as second die 151 illustrated in FIG. 1A or a different subsequent die in the stacked semiconductor device). In the same or other embodiments, the metal pad embedded in the first semiconductor substrate 502 (e.g., part of the first die such as first die 101) may facilitate power distribution from the first semiconductor substrate 502 to components of the one or more underlying dies included in the imaging system 500.

Reference throughout this specification to “one example” or “one embodiment” means that a particular feature, structure, or characteristic described in connection with the embodiment is included in at least one embodiment of the present invention. Thus, the appearances of the phrases “in one example” or “one embodiment” in various places throughout this specification are not necessarily all referring to the same embodiment. Furthermore, the particular features, structures, or characteristics can be combined in any suitable manner in one or more embodiments.

It will be understood that, although the terms first, second, third, etc., may be used herein to describe various elements, these elements should not be limited by these terms and should not be used to determine the process sequence or formation order of associated elements. Unless indicated otherwise, these terms are only used to distinguish one element from another element. Thus, a first element discussed below could be termed a second element without departing from the teachings of the disclosed embodiments.

Spatially relative terms, such as “beneath,” “below,” “over,” “under,” “above,” “upper,” “top,” “bottom,” “left,” “right,” “center,” “middle,” and the like, can be used herein for ease of description to describe one element or feature's relationship relative to another element(s) or feature(s) as illustrated in the figures. It will be understood that the spatially relative terms are intended to encompass different orientations of the device in use or operation in addition to the orientation depicted in the figures. For example, if the device in the figures is rotated or turned over, elements described as “below” or “beneath” or “under” other elements or features would then be oriented “above” the other elements or features. Thus, the exemplary terms “below” and “under” can encompass both an orientation of above and below. The device can be otherwise oriented (rotated ninety degrees or at other orientations) and the spatially relative descriptors used herein are interpreted accordingly. In addition, it will also be understood that when an element is referred to as being “between” two other elements, it can be the only element between the two other elements, or one or more intervening elements can also be present.

Throughout this specification, several terms of art are used. These terms are to take on their ordinary meaning in the art from which they come, unless specifically defined herein or the context of their use would clearly suggest otherwise. It should be noted that element names and symbols can be used interchangeably through this document (e.g., Si vs. silicon); however, both have identical meaning.

The processes explained above can be implemented using software and/or hardware. The techniques described can constitute machine-executable instructions embodied within a tangible or non-transitory machine (e.g., computer) readable storage medium, that when executed by a machine (e.g., controller 550 of FIG. 5) will cause the machine to perform the operations described. Additionally, the processes can be embodied within hardware, such as an application specific integrated circuit (“ASIC”), field programmable gate array (FPGA), or otherwise.

A tangible machine-readable storage medium includes any mechanism that provides (i.e., stores) information in a non-transitory form accessible by a machine (e.g., a computer, network device, personal digital assistant, manufacturing tool, any device with a set of one or more processors, etc.). For example, a machine-readable storage medium includes recordable/non-recordable media (e.g., read only memory (ROM), random access memory (RAM), magnetic disk storage media, optical storage media, flash memory devices, etc.).

The above description of illustrated examples of the invention, including what is described in the Abstract, is not intended to be exhaustive or to limit the invention to the precise forms disclosed. While specific examples of the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific examples disclosed in the specification. Rather, the scope of the invention is to be determined entirely by the following claims, which are to be construed in accordance with established doctrines of claim interpretation.

What is claimed is:

1. A stacked semiconductor device, comprising:
a first die including a first semiconductor substrate and a first interconnect stack;
a second die including a second semiconductor substrate and a second interconnect stack, wherein the first interconnect stack and the second interconnect stack are disposed between the first semiconductor substrate and the second semiconductor substrate;
a plurality of first bonding pads disposed within the first interconnect stack and a plurality of second bonding pads disposed within the second interconnect stack, wherein the plurality of first bonding pads contact the plurality of second bonding pads at a bonding interface to form a plurality of bonding connections, the plurality of bonding connections including rail connections and signal connections; and
a metal pad embedded in the first semiconductor substrate, wherein the metal pad is coupled to a first rail connection included in the rail connections, and wherein the metal pad extends laterally between a first pair of the plurality of bonding connections when the stacked semiconductor device is viewed from a plan view.

2. The stacked semiconductor device of claim 1, further comprising:
a second rail connection included in the rail connections, the second rail connection coupled to the metal pad; and
a first metal wire coupled to the first rail connection and the second rail connection, wherein the first metal wire is disposed within the second interconnect stack, wherein the metal pad and the first metal wire respectively provide a first conductive path and a second conductive path coupled in parallel through the first rail connection and the second rail connection, wherein the first metal wire and the metal pad each extend laterally from the first rail connection to the second rail connection.

3. The stacked semiconductor device of claim 2, wherein the first metal wire extends laterally between the first pair of the plurality of bonding connections when viewed from the plan view, wherein the metal pad has a first width and the first metal wire has a second width, wherein the first width is greater than the second width.

4. The stacked semiconductor device of claim 2, wherein the metal pad and the first metal wire are arranged such that the metal pad covers, at least in part, the first metal wire when viewed from the plan view, and wherein the first pair of the plurality of bonding connections are included in the signal connections.

5. The stacked semiconductor device of claim 2, further comprising:
a second metal wire coupled to a third rail connection and a fourth rail connection included in the rail connections, wherein the first metal wire extends alongside the second metal wire between the first pair of the plurality of bonding connections, wherein the second metal wire is coupled to the metal pad to provide a third conductive path extending from the third rail connection to the fourth rail connection.

6. The stacked semiconductor device of claim 5, wherein the metal pad extends over both the first metal wire and the second metal wire, and wherein one or more bonding connections included in the plurality of bonding connections are disposed between the first metal wire and the second metal wire when viewed from the plan view.

7. The stacked semiconductor device of claim 2, wherein the second interconnect stack includes a plurality of metal layers including a distal metal layer disposed closer to the bonding interface than any other metal layer included in the plurality of metal layers, and wherein the first metal wire is included in the distal metal layer.

8. The stacked semiconductor device of claim 2, wherein the first conductive path and the second conductive path extend from the first rail connection to the second rail connection a first distance along a first direction, and wherein individual bonding connections included in the first pair of the plurality of bonding connections are separated by a second distance extending along a second direction perpendicular to the first direction when viewed from the plan view.

9. The stacked semiconductor device of claim 1, further comprising an isolation trench formed within the first semiconductor substrate, wherein the metal pad is disposed within the isolation trench, and wherein the isolation trench is filled with an isolation material surrounding the metal pad to electrically isolate the metal pad from a substrate material of the first semiconductor substrate.

10. The stacked semiconductor device of claim 9, wherein the isolation trench includes an opening extending through the isolation material to expose a surface of the metal pad, and wherein the opening defines a contact window for the metal pad to enable an external connection to the metal pad.

11. The stacked semiconductor device of claim 9, wherein the first interconnect stack includes a plurality of metal layers including a proximal metal layer disposed closer to the first semiconductor substrate any other metal layer included in the plurality of metal layers, wherein the proximal metal layer includes a plurality of metal wires including a first proximal wire and a second proximal wire adjacent to the first proximal wire without any intervening metal wires included in the proximal metal layer disposed therebetween, wherein the first proximal wire is separated from the second proximal wire by a separation region within the first interconnect stack, and wherein respective boundaries of the metal pad and the isolation trench overlap with the separation region.

12. The stacked semiconductor device of claim 1, wherein the first die includes a plurality of photodiodes disposed within the first semiconductor substrate and arranged in rows and columns to form a pixel cell array, wherein the first die further includes a plurality of contact pads laterally surrounding the pixel cell array when viewed from the plan view, and wherein the plurality of contact pads includes the metal pad.

13. The stacked semiconductor device of claim 1, wherein the second die includes circuitry disposed in or on the second semiconductor substrate, and wherein the metal pad is coupled to the circuitry through the first rail connection to provide a supply voltage to the circuitry.

14. The stacked semiconductor device of claim 1, wherein the plurality of bonding connections include metal-metal bonds associated with the plurality of first bonding pads contacting the plurality of second bonding pads, wherein individual bonding pads included in the plurality of first bonding pads and the plurality of second bonding pads are arranged in rows and columns to form an array of bonding connections collectively corresponding to the plurality of bonding connections, wherein the first pair of bonding connections are in a same column included in the columns, wherein the first pair of bonding connections are in different rows included in the rows, and wherein the metal pad extends between the different rows when viewed from the plan view.

15. An image sensor, comprising:
a first die including a first interconnect stack and a plurality of photodiodes disposed within a first semiconductor substrate to form a pixel cell array;
a second die including a second interconnect stack and a second semiconductor substrate having integrated circuitry, wherein the first interconnect stack and the second interconnect stack are disposed between the first semiconductor substrate and the second semiconductor substrate;
a plurality of first bonding pads disposed within the first interconnect stack and a plurality of second bonding pads disposed within the second interconnect stack, wherein the plurality of first bonding pads contact the plurality of second bonding pads at a bonding interface to form a plurality of bonding connections, the plurality of bonding connections including rail connections and signal connections; and
a metal pad embedded in the first semiconductor substrate, wherein the metal pad is coupled to a first rail connection included in the rail connections, and wherein the metal pad extends laterally between a first pair of the plurality of bonding connections when the image sensor is viewed from a plan view.

16. The image sensor of claim 15, further comprising a plurality of contact pads laterally surrounding the pixel cell array when viewed from the plan view, and wherein the plurality of contact pads included the metal pad.

17. The image sensor of claim 15, further comprising:
a second rail connection included in the rail connections, the second rail connection coupled to the metal pad; and
a first metal wire coupled to the first rail connection and the second rail connection, wherein the first metal wire is disposed within the second interconnect stack, wherein the metal pad and the first metal wire respectively provide a first conductive path and a second conductive path coupled in parallel, each extending from the first rail connection to the second rail connection.

18. The image sensor of claim 17, further comprising:
a second metal wire coupled to a third rail connection and a fourth rail connection included in the rail connections, wherein the first metal wire extends alongside the second metal wire between the first pair of bonding connections, wherein the second metal wire is coupled to the metal pad to provide a third conductive path extending from the third rail connection to the fourth rail connection.

19. The image sensor of claim 17, wherein the first conductive path and the second conductive path extending from the first rail connection to the second rail connection is along a first direction, and wherein individual bonding connections included in the first pair of the plurality of bonding connections are separated by a distance extending along a second direction perpendicular to the second direction when viewed from the plan view.

20. The image sensor of claim 15, further comprising an isolation trench disposed within the first semiconductor substrate, wherein the metal pad is disposed within the isolation trench, wherein the isolation trench is filled with an isolation material surrounding the metal pad to electrically isolate the metal pad from the first semiconductor substrate, wherein the isolation trench includes an opening extending through the isolation material to expose a surface of the metal pad, and wherein the opening defines a contact window for the metal pad to enable an external connection to the metal pad.
